(19) United States
(12) Patent Application Publication
(10) Pub. No.: US 2025/0324828 A1
(43) Pub. Date: Oct. 16, 2025

(54) DISPLAY PANEL, MANUFACTURING METHOD FOR DISPLAY PANEL, AND ELECTRONIC DEVICE

(71) Applicants: Hefei Visionox Technology Co., Ltd., Hefei (CN); Visionox Technology Inc., Suzhou (CN)

(72) Inventors: Yuting FU, Hefei (CN); Cheng-Yi LIN, Hefei (CN); Cheng-Chu TSENG, Hefei (CN); Wei-Ju HUANG, Hefei (CN); Yi-Yu LAI, Hefei (CN); Jui-Yang TSAI, Hefei (CN); Hsiang-Yin HOU, Hefei (CN); Liping XU, Hefei (CN); Chung-Chun LEE, Hefei (CN)

(73) Assignees: Hefei Visionox Technology Co., Ltd., Hefei (CN); Visionox Technology Inc., Suzhou (CN)

(21) Appl. No.: 18/782,412

(22) Filed: Jul. 24, 2024

(30) Foreign Application Priority Data
Apr. 16, 2024 (CN) 202410460492.6

(51) Int. Cl. H01L 33/54; H01L 25/075; H01L 33/56; H01L 33/62

(52) U.S. Cl. CPC H10H 20/853; H01L 25/0753; H10H 20/854; H10H 20/857; H10H 20/032; H10H 20/0362

(57) ABSTRACT

A display panel includes an array substrate, an isolation structure, a light-emitting unit, and a first encapsulation layer. The isolation structure encloses and forms an isolation opening. At least part of a light-emitting unit is located in the isolation opening. The light-emitting unit includes a first light-emitting unit and a second light-emitting unit. The first encapsulation layer is located on a side of the light-emitting unit away from the array substrate. The first encapsulation layer includes a plurality of encapsulation units spaced apart. The encapsulation units extend from a side surface of the isolation structure to a side of the isolation structure away from the array substrate.

### CROSS REFERENCE TO RELATED APPLICATION

The present application claims priority to Chinese Patent Application No. 202410460492.6 filed on Apr. 16, 2024, and titled “DISPLAY PANEL, MANUFACTURING METHOD FOR DISPLAY PANEL, AND ELECTRONIC DEVICE”, which is incorporated herein by reference in its entirety.

### TECHNICAL FIELD

The present application relates to the technical field of display, and in particular, to a display panel, a manufacturing method for a display panel, and an electronic device.

### BACKGROUND

An organic light emitting display (OLED) and a flat display apparatus based on a light emitting diode (LED) technology are widely used in various consumer electronic products such as mobile phones, TVs, notebook computers, and desktop computers due to advantages such as high image quality, power saving, a thin body, and a wide range of applications, becoming the mainstream in display panels.

However, the display panels still have some problems that need to be urgently solved.

### SUMMARY

In order to overcome the technical problems mentioned in the Background, an embodiment of the present application provides a display panel, the display panel including: an array substrate;
an isolation structure located on one side of the array substrate, the isolation structure enclosing and forming an isolation opening;
a light-emitting unit at least partially located in the isolation opening, the light-emitting unit including a first light-emitting unit and a second light-emitting unit; and
a first encapsulation layer located on a side of the light-emitting unit away from the array substrate, the first encapsulation layer including a plurality of encapsulation units spaced apart, the encapsulation units extending from a side surface of the isolation structure to a side of the isolation structure away from the array substrate, the side surface of the isolation structure being a surface of the isolation structure facing the isolation opening; a taper angle being formed between a side of a portion of the encapsulation unit located on the side of the isolation structure away from the array substrate close to the isolation structure and a side of the portion away from the isolation opening, and a taper angle of the encapsulation unit corresponding to the first light-emitting unit being not equal to a taper angle of the encapsulation unit corresponding to the second light-emitting unit.

In some possible implementations, the present application further provides another display panel, the display panel including:
an array substrate;
an isolation structure located on one side of the array substrate, the isolation structure enclosing and forming an isolation opening;
a light-emitting unit at least partially located in the isolation opening; and
a first encapsulation layer located on a side of the light-emitting unit away from the array substrate, the first encapsulation layer including a plurality of encapsulation units spaced apart, the encapsulation units extending from a side surface of the isolation structure to a side of the isolation structure away from the array substrate, the side surface of the isolation structure being a surface of the isolation structure facing the isolation opening; a taper angle being formed between a side of a portion of the encapsulation unit located on the side of the isolation structure away from the array substrate close to the isolation structure and a side of the portion away from the isolation opening, the taper angle being less than 90°.

In some possible implementations, the present application further provides a manufacturing method for a display panel, the method including:
providing an array substrate;
forming an isolation structure on one side of the array substrate, the isolation structure enclosing and forming an isolation opening; and
forming at least part of a light-emitting unit in the isolation opening, and forming a first encapsulation layer on a side of the light-emitting unit away from the array substrate, the light-emitting unit including a first light-emitting unit and a second light-emitting unit, the first encapsulation layer including a plurality of encapsulation units spaced apart, the encapsulation units extending from a side surface of the isolation structure to a side of the isolation structure away from the array substrate, the side surface of the isolation structure being a surface of the isolation structure facing the isolation opening; a taper angle being formed between a side of a portion of the encapsulation unit located on the side of the isolation structure away from the array substrate close to the isolation structure and a side of the portion away from the isolation opening, and a taper angle of the encapsulation unit corresponding to the first light-emitting unit being not equal to a taper angle of the encapsulation unit corresponding to the second light-emitting unit.

In some possible implementations, the present application further provides an electronic device. The electronic device includes the display panel in the present application or includes a display panel manufactured with the manufacturing method for a display panel in the present application.

Compared with the prior art, the present application has the following beneficial effects.

According to the display panel, the manufacturing method for a display panel, and the electronic device provided in the present application, the first encapsulation layer remaining on the side wall of the isolation structure corresponding to the second light-emitting unit is side-etched, so that the taper angle of the encapsulation unit corresponding to the first light-emitting unit is not equal to the taper angle of the encapsulation unit corresponding to the second light-emitting unit. Finally, the second electrodes of the first light-emitting unit and the second light-emitting unit can effectively overlap with the corresponding isolation structure, thereby improving the display effect of the display panel.

### BRIEF DESCRIPTION OF THE DRAWINGS

FIG. 1 is a schematic cross-sectional view of a display panel in the related art according to an embodiment of the present application;

FIG. 2 is a schematic cross-sectional view I of a display panel according to an embodiment of the present application;

FIG. 3 is a schematic cross-sectional view II of the display panel according to an embodiment of the present application;

FIG. 4 is a schematic cross-sectional view of the display panel when an isolation structure includes a three-layer structure according to an embodiment of the present application;

FIG. 5 is a schematic flowchart of a manufacturing method for a display panel according to an embodiment of the present application;

FIG. 6 is a schematic cross-sectional view of forming a first electrode layer on one side of an array substrate according to an embodiment of the present application;

FIG. 7 is a schematic cross-sectional view of forming a pixel defining layer on a side of the first electrode layer away from the array substrate according to an embodiment of the present application;

FIG. 8 is a schematic cross-sectional view of forming an isolation structure on a side of the pixel defining layer away from the array substrate according to an embodiment of the present application;

FIG. 9 is a schematic cross-sectional view of forming a light-emitting functional layer of a first light-emitting unit on a side of the isolation structure away from the array substrate according to an embodiment of the present application;

FIG. 10 is a schematic cross-sectional view of forming a second electrode layer on a side of the light-emitting functional layer of the first light-emitting unit away from the array substrate according to an embodiment of the present application;

FIG. 11 is a schematic cross-sectional view of forming a first encapsulation layer on a side of the second electrode layer away from the array substrate according to an embodiment of the present application;

FIG. 12 is a schematic cross-sectional view of forming a first etching protection layer in an isolation opening corresponding to the first light-emitting unit according to an embodiment of the present application;

FIG. 13 is a schematic cross-sectional view after the first encapsulation layer, the light-emitting functional layer, and the second electrode layer that are not covered by the first etching protection layer are removed along a direction perpendicular to the array substrate according to an embodiment of the present application;

FIG. 14 is a schematic cross-sectional view after the first encapsulation layer on side walls of the isolation structure corresponding to a second light-emitting unit and a third light-emitting unit is laterally removed according to an embodiment of the present application;

FIG. 15 is a schematic cross-sectional view of forming a light-emitting functional layer of the second light-emitting unit on the side of the isolation structure away from the array substrate according to an embodiment of the present application;

FIG. 16 is a schematic cross-sectional view of forming a second electrode layer on a side of the light-emitting functional layer of the second light-emitting unit away from the array substrate according to an embodiment of the present application;

FIG. 17 is a schematic cross-sectional view of forming the first encapsulation layer on the side of the second electrode layer away from the array substrate according to an embodiment of the present application;

FIG. 18 is a schematic cross-sectional view of forming a second etching protection layer in an isolation opening corresponding to the second light-emitting unit according to an embodiment of the present application;

FIG. 19 is a schematic cross-sectional view after the first encapsulation layer, the light-emitting functional layer, and the second electrode layer of the second light-emitting unit that are not covered by the second etching protection layer are removed along the direction perpendicular to the array substrate according to an embodiment of the present application;

FIG. 20 is a schematic cross-sectional view after the first encapsulation layer on a side wall of the isolation structure corresponding to the third light-emitting unit is laterally removed according to an embodiment of the present application;

FIG. 21 is a schematic cross-sectional view of forming a light-emitting functional layer of a third light-emitting unit on the side of the isolation structure away from the array substrate according to an embodiment of the present application;

FIG. 22 is a schematic cross-sectional view of forming a second electrode layer on a side of the light-emitting functional layer of the third light-emitting unit away from the array substrate according to an embodiment of the present application;

FIG. 23 is a schematic cross-sectional view of forming the first encapsulation layer on the side of the second electrode layer away from the array substrate according to an embodiment of the present application;

FIG. 24 is a schematic cross-sectional view of forming a third etching protection layer in an isolation opening corresponding to the third light-emitting unit according to an embodiment of the present application; and

FIG. 25 is a schematic cross-sectional view after the first encapsulation layer, the light-emitting functional layer, and the second electrode layer of the third light-emitting unit that are not covered by the third etching protection layer are removed along the direction perpendicular to the array substrate according to an embodiment of the present application.

Reference signs: 1: array substrate; 2: first electrode; 3: pixel defining layer; 31: pixel opening; 4: light-emitting portion; 5: second electrode; 6: isolation opening; 7: isolation structure; 71: first isolation portion; 72: second isolation portion; 73: third isolation portion; 8: light-emitting unit; 9: first encapsulation layer; 91: encapsulation unit; 10: first etching protection layer; 11: second etching protection layer; 12: third etching protection layer.

### DETAILED DESCRIPTION

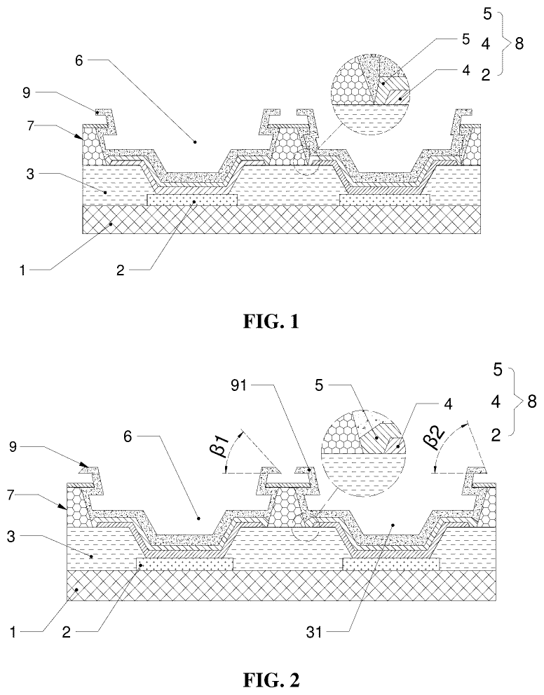

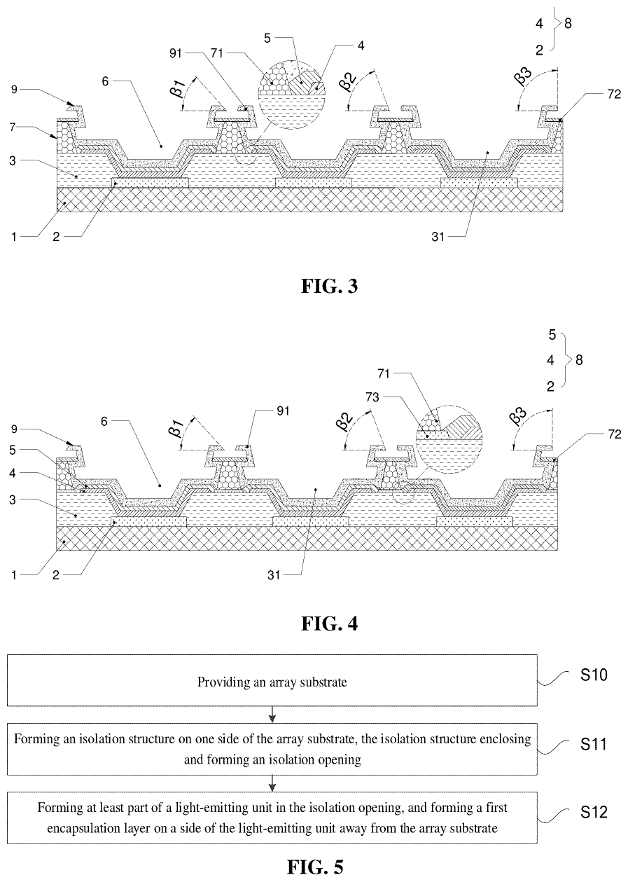

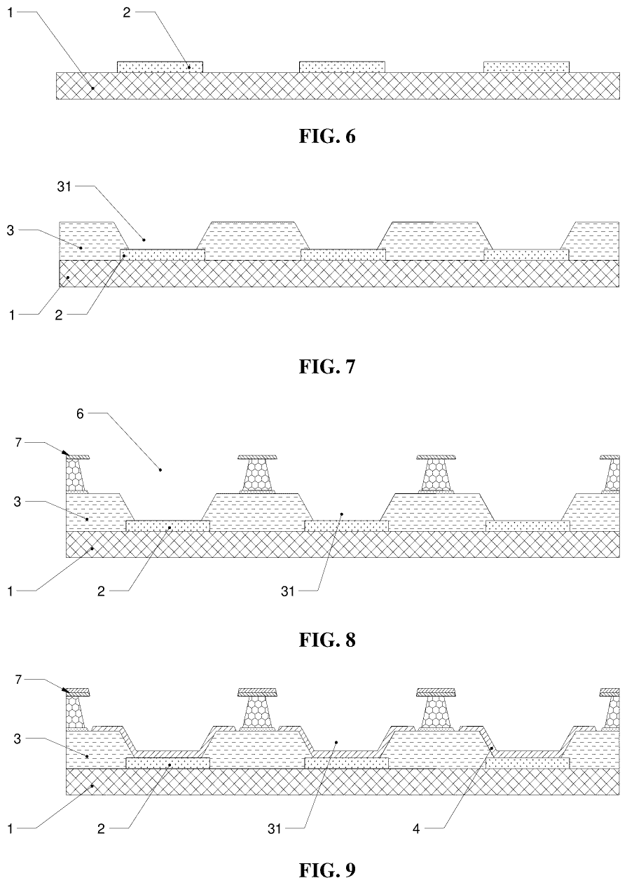

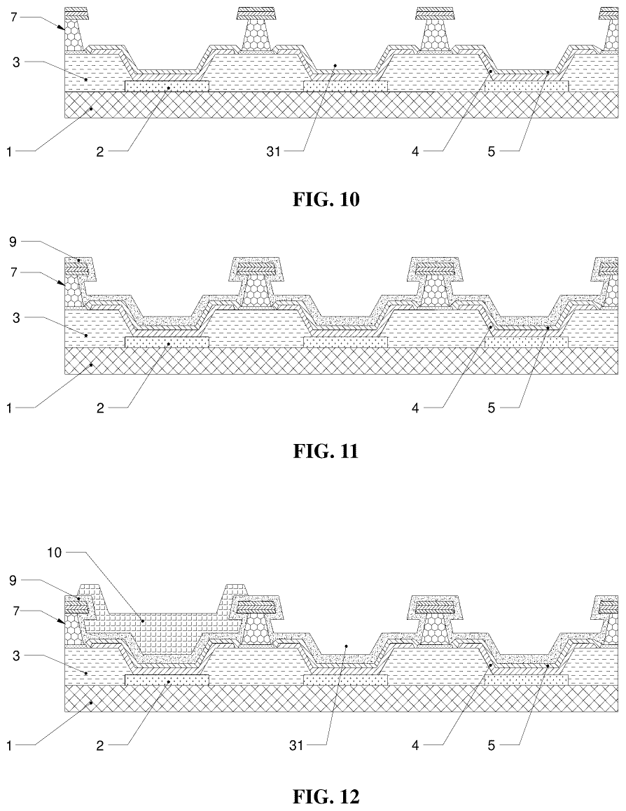

Referring to FIG. 1, the display panel in the related art includes an array substrate 1, an isolation structure 7 located on one side of the array substrate 1, a light-emitting unit 8 at least partially located in an isolation opening 6 enclosed and formed by the isolation structure 7, and a first encapsulation layer 9 located on a side of the light-emitting unit 8 away from the array substrate 1. The light-emitting unit 8 includes a first light-emitting unit and a second light-emitting unit. According to a manufacturing sequence of the first light-emitting unit and the second light-emitting unit, after the first light-emitting unit is formed, part of the first encapsulation layer 9 may remain on a side wall of the isolation structure 7 corresponding to the second light-emitting unit, and after the second light-emitting unit is formed, it is difficult for a second electrode 5 of the second light-emitting unit to effectively overlap with the side wall of the isolation structure 7 corresponding to the second light-emitting unit, thereby affecting a display effect of the display panel.

In view of this, this embodiment provides a solution that can improve the display effect of the display panel. The solution provided in this embodiment is described in detail below.

Referring to FIG. 2, this embodiment provides a display panel. The display panel includes an array substrate 1, an isolation structure 7, a light-emitting unit 8, and a first encapsulation layer 9.

The array substrate 1 may include a base and a plurality of driving units located on one side of the base. Each driving unit may include one or more semiconductor switching devices. The semiconductor switching device may be formed by a plurality of film layers in the array substrate 1 through cooperation. For example, the semiconductor switching device may be a thin film transistor formed by a plurality of film layers through cooperation.

The isolation structure 7 is located on one side of the array substrate 1. The isolation structure 7 encloses and forms an isolation opening 6.

Composition, manufacturing, and the like of the isolation structure 7 are further described in patents PCT/CN2023/134518, 202310759370.2, 202310740412.8, 202310707209.0, 202311346196.5, 202311499823.9, 202310731471.9, and 202311091555.7 for reference.

At least part of the light-emitting unit 8 is located in the isolation opening 6. The light-emitting unit 8 includes a first light-emitting unit and a second light-emitting unit. The first light-emitting unit and the second light-emitting unit emit light in different colors. For example, the first light-emitting unit may be red, and the second light-emitting unit may be green.

The first encapsulation layer 9 is located on a side of the light-emitting unit 8 away from the array substrate 1. The first encapsulation layer 9 includes a plurality of encapsulation units 91 spaced apart. The encapsulation units 91 extend from a side surface of the isolation structure 7 to a side of the isolation structure 7 away from the array substrate 1. The side surface of the isolation structure 7 is a surface of the isolation structure 7 facing the isolation opening 6. A taper angle is formed between a side of a portion of the encapsulation unit 91 located on the side of the isolation structure 7 away from the array substrate 1 close to the isolation structure 7 and a side of the portion away from the isolation opening 6, and a taper angle β1 of the encapsulation unit 91 corresponding to the first light-emitting unit is not equal to a taper angle β2 of the encapsulation unit 91 corresponding to the second light-emitting unit.

According to a manufacturing sequence of the first light-emitting unit and the second light-emitting unit, after the first light-emitting unit is manufactured, the first encapsulation layer 9 remaining on a side wall of the isolation structure 7 corresponding to the second light-emitting unit is etched away by side etching, and when the first encapsulation layer 9 remaining on the side wall of the isolation structure 7 corresponding to the second light-emitting unit is etched, a portion of the encapsulation unit 91 corresponding to the first light-emitting unit located on the side of the isolation structure 7 away from the array substrate 1 may be side-etched.

Since no other light-emitting units 8 may be manufactured after the second light-emitting unit in this embodiment, after the second light-emitting unit is manufactured, there is no need to side-etch a portion of the encapsulation unit 91 corresponding to the second light-emitting unit on the side of the isolation structure 7 away from the array substrate 1. Therefore, a taper angle β1 formed between a side of the portion of the encapsulation unit 91 corresponding to the first light-emitting unit located on the side of the isolation structure 7 away from the array substrate 1 close to the isolation structure 7 and the side of the portion away from the isolation opening 6 is not equal to a taper angle β2 formed between a side of the portion of the encapsulation unit 91 corresponding to the second light-emitting unit on the side of the isolation structure 7 away from the array substrate 1 close to the isolation structure 7 and a side of the portion away from the isolation opening 6.

Since the first encapsulation layer 9 remaining on the side wall of the isolation structure 7 corresponding to the second light-emitting unit is etched before the second light-emitting unit is manufactured, a second electrode 5 of the second light-emitting unit may effectively overlap with the corresponding isolation structure 7, thereby improving a display effect of the second light-emitting unit and improving the display effect of the display panel.

Based on the above design, in this embodiment, the first encapsulation layer 9 remaining on the side wall of the isolation structure 7 corresponding to the second light-emitting unit is side-etched, so that the taper angle β1 of the encapsulation unit 91 corresponding to the first light-emitting unit is not equal to the taper angle β2 of the encapsulation unit 91 corresponding to the second light-emitting unit. Finally, the second electrodes 5 of the first light-emitting unit and the second light-emitting unit can effectively overlap with the corresponding isolation structure 7, thereby improving the display effect of the display panel.

In some possible implementations, referring to FIG. 3, the display panel further includes a third light-emitting unit, and a taper angle of the encapsulation unit 91 corresponding to the third light-emitting unit is not equal to the taper angles of the encapsulation units 91 corresponding to the first light-emitting unit and the second light-emitting unit.

The first light-emitting unit, the second light-emitting unit, and the third light-emitting unit emit light in different colors. For example, the first light-emitting unit may be red, the second light-emitting unit may be green, and the third light-emitting unit may be blue.

According to a manufacturing sequence of the first light-emitting unit, the second light-emitting unit, and the third light-emitting unit, after the first light-emitting unit is manufactured, the first encapsulation layer 9 remaining on side walls of the isolation structure 7 corresponding to the second light-emitting unit and the third light-emitting unit is etched away by side etching, and when the first encapsulation layer 9 remaining on the side walls of the isolation structure 7 corresponding to the second light-emitting unit and the third light-emitting unit is etched, a portion of the encapsulation unit 91 corresponding to the first light-emitting unit located on the side of the isolation structure 7 away from the array substrate 1 may be side-etched.

After the second light-emitting unit is manufactured, the first encapsulation layer 9 remaining on a side wall of the isolation structure 7 corresponding to the third light-emitting unit is etched away by side etching, and when the first encapsulation layer 9 remaining on the side wall of the isolation structure 7 corresponding to the third light-emitting unit is etched, a portion of the encapsulation unit 91 corresponding to the second light-emitting unit on the side of the isolation structure 7 away from the array substrate 1 may be side-etched.

Since no other light-emitting units 8 may be manufactured after the third light-emitting unit in this embodiment, after the third light-emitting unit is manufactured, there is no need to side-etch a portion of the encapsulation unit 91 corresponding to the third light-emitting unit on the side of the isolation structure 7 away from the array substrate 1. Therefore, the taper angle β1 formed between the side of the portion of the encapsulation unit 91 corresponding to the first light-emitting unit located on the side of the isolation structure 7 away from the array substrate 1 close to the isolation structure 7 and the side of the portion away from the isolation opening 6 is not equal to the taper angle β2 formed between a side of the portion of the encapsulation unit 91 corresponding to the second light-emitting unit on the side of the isolation structure 7 away from the array substrate 1 close to the isolation structure 7 and a side of the portion away from the isolation opening 6 and a taper angle β3 formed between a side of the portion of the encapsulation unit 91 corresponding to the third light-emitting unit on the side of the isolation structure 7 away from the array substrate 1 close to the isolation structure 7 and a side of the portion away from the isolation opening 6.

Since the first encapsulation layer 9 remaining on the side wall of the isolation structure 7 corresponding to the second light-emitting unit is etched before the second light-emitting unit is manufactured, the second electrode 5 of the second light-emitting unit may effectively overlap with the corresponding isolation structure 7. Since the first encapsulation layer 9 remaining on the side wall of the isolation structure 7 corresponding to the third light-emitting unit is etched before the third light-emitting unit is manufactured, the second electrode 5 of the third light-emitting unit may effectively overlap with the corresponding isolation structure 7, thereby improving display effects of the second light-emitting unit and the third light-emitting unit and improving the display effect of the display panel.

In some possible implementations, referring to FIG. 3 again, the taper angle β1 of the encapsulation unit 91 corresponding to the first light-emitting unit ranges from 30° to 60°. For example, the taper angle β1 may be 30°, 35°, 45°, 50°, 55°, 60°, or the like. Through the reasonable setting of the taper angle β1, the encapsulation unit 91 remaining on the side wall of the isolation structure 7 corresponding to the second light-emitting unit can be etched more cleanly, so that the second electrode 5 of the second light-emitting unit can more effectively overlap with the corresponding isolation structure 7.

In some possible implementations, referring to FIG. 3 again, the taper angle β2 of the encapsulation unit 91 corresponding to the second light-emitting unit ranges from 30° to 80°. For example, the taper angle β2 may be 30°, 35°, 45°, 55°, 65°, 75°, 80°, or the like. Through the reasonable setting of the taper angle β2, the encapsulation unit 91 remaining on the side wall of the isolation structure 7 corresponding to the third light-emitting unit can be etched more cleanly, so that the second electrode 5 of the third light-emitting unit can more effectively overlap with the corresponding isolation structure 7.

Preferably, referring to FIG. 3 again, the taper angle β3 of the encapsulation unit 91 corresponding to the third light-emitting unit ranges from 80° to 90°. For example, the taper angle β3 may be 80°, 82°, 85°, 88°, 90°, or the like. After the third light-emitting unit is manufactured, through the reasonable setting of the taper angle β3, the step of side-etching the encapsulation unit corresponding to the third light-emitting unit can be reduced, thereby reducing manufacturing costs of the display panel.

Generally, since no other light-emitting units 8 may be manufactured after the third light-emitting unit in this embodiment, after the third light-emitting unit is manufactured, there is no need to side-etch a portion of the encapsulation unit 91 corresponding to the third light-emitting unit on the side of the isolation structure 7 away from the array substrate 1. Therefore, the theoretical taper angle β3 of the encapsulation unit 91 corresponding to the third light-emitting unit is 90°. During the manufacturing, there may be a certain error. Therefore, the taper angle β3 of the encapsulation unit 91 corresponding to the third light-emitting unit may range from 80° to 90°.

In some possible implementations, referring to FIG. 3 again, adjacent encapsulation units 91 are spaced apart on the side of the isolation structure 7 away from the array substrate 1. A gap exists between the portion of the encapsulation unit 21 located on the side of the isolation structure 7 away from the array substrate 1 and the side of the isolation structure 7 away from the array substrate 1. A material of the first encapsulation layer 9 includes an inorganic material.

When the first encapsulation layer 9 is formed, the first encapsulation layer 9 may be disconnected at the isolation structure 7 and form a plurality of encapsulation units 91 spaced apart, and the encapsulation units 91 may encapsulate the light-emitting unit 8 separately, thereby improving display characteristics of the display panel.

In some possible implementations, referring to FIG. 3 again, the light-emitting unit 8 includes a first electrode layer, a light-emitting functional layer, and a second electrode layer sequentially stacked along a direction away from the array substrate 1, the display panel further includes a pixel defining layer 3 located on a side of the first electrode layer away from the array substrate 1, and the isolation structure 7 is located on a side of the pixel defining layer 3 away from the array substrate 1. The pixel defining layer 3 includes pixel openings 31 exposing at least part of the first electrode 2, and an orthographic projection of the isolation structure 7 on the array substrate 1 is located between orthographic projections of two adjacent pixel openings 31 on the array substrate 1. The orthographic projection of the pixel opening 31 on the array substrate 1 is located within an orthographic projection of the isolation opening 6 on the array substrate 1.

When the light-emitting functional layer is formed, the light-emitting functional layer may be partitioned by the isolation structure 7 to form a plurality of light-emitting portions 4 spaced apart. When the second electrode layer is formed, the second electrode layer may be partitioned by the isolation structure 7 to form a plurality of second electrodes 5 spaced apart. The isolation structure 7 includes a conductive material. The second electrode 5 is electrically connected to the isolation structure 7. One first electrode 2, one light-emitting portion 4, and one second electrode 5 form one light-emitting unit 8. The first electrode 2 is an anode or a cathode, and the second electrode 5 is a cathode or an anode. When the first electrode 2 is an anode, the second electrode 5 is a cathode. When the first electrode 2 is a cathode, the second electrode 5 is an anode.

In some embodiments, the pixel defining layer 3 may further include a concave portion, and the isolation structure 7 is located in the concave portion.

In some possible implementations, referring to FIG. 3 again, the isolation structure 7 includes a first isolation portion 71 and a second isolation portion 72 sequentially stacked along a direction away from the array substrate 1, and an orthographic projection of the first isolation portion 71 on the array substrate 1 is located within an orthographic projection of the second isolation portion 72 on the array substrate 1.

Since the second isolation portion 72 is located on a side of the first isolation portion 71 away from the array substrate 1 and a transverse width of the second isolation portion 72 is greater than a transverse width of the first isolation portion 71, the second isolation portion 72 may disconnect the light-emitting functional layer from the second electrode layer at the isolation structure 7. In this way, the isolation structure 7 formed by the first isolation portion 71 and the second isolation portion 72 can more easily encapsulate the light-emitting units 8 separately.

In some possible implementations, referring to FIG. 3 again, the second electrode 5 of the light-emitting unit 8 is electrically connected to the first isolation portion 71. Referring to FIG. 4, additionally/alternatively, the isolation structure 7 further includes a third isolation portion 73 located on a side of the first isolation portion 71 facing the array substrate 1, and the second electrode 5 of the light-emitting unit 8 is electrically connected to the third isolation portion 73. A material of the third isolation portion 73 includes metal, such as molybdenum; a material of the first isolation portion 71 includes metal, such as aluminum; a material of the second isolation portion 72 includes metal, such as titanium. In this way, when the isolation structure 7 partitions the second electrode layer into the second electrodes 5, the second electrodes 5 are more easily electrically connected to the first isolation portion 71, or the third isolation portion 73, or the first isolation portion 71 and the third isolation portion 73.

In some possible implementations, the present application further provides another display panel. The display panel includes an array substrate 1, an isolation structure 7, a light-emitting unit 8, and a first encapsulation layer 9.

The isolation structure 7 is located on one side of the array substrate 1. The isolation structure 7 encloses and forms an isolation opening 6.

At least part of the light-emitting unit 8 is located in the isolation opening 6. The first encapsulation layer 9 is located on a side of the light-emitting unit 8 away from the array substrate 1. The first encapsulation layer 9 includes a plurality of encapsulation units 91 spaced apart. The encapsulation units 91 extend from a side surface of the isolation structure 7 to a side of the isolation structure 7 away from the array substrate 1. The side surface of the isolation structure 7 is a surface of the isolation structure 7 facing the isolation opening 6. A taper angle is formed between a side of a portion of the encapsulation unit 91 located on the side of the isolation structure 7 away from the array substrate 1 close to the isolation structure 7 and a side of the portion away from the isolation opening 6, and the taper angle is less than 90°.

During the manufacturing of the light-emitting unit 8, the first encapsulation layer 9 remaining on a side wall of the isolation structure 7 corresponding to the light-emitting unit 8 is etched away by side etching, to etch away the remaining first encapsulation layer 9. While the remaining first encapsulation layer 9 is etched, a portion of the encapsulation unit 91 corresponding to the corresponding light-emitting unit 8 located on the side of the isolation structure 7 away from the array substrate 1 may be side-etched, so that a taper angle of the encapsulation unit 91 corresponding to the light-emitting unit is less than 90°.

Since the first encapsulation layer 9 remaining on the side wall of the isolation structure 7 corresponding to the light-emitting unit 8 is etched away, the second electrode 5 of the light-emitting unit 8 can effectively overlap with the corresponding isolation structure 7, thereby improving the display effect of the display panel.

In some possible implementations, the light-emitting unit 8 includes a first light-emitting unit and a second light-emitting unit, and a taper angle β1 of the encapsulation unit 91 corresponding to the first light-emitting unit ranges from 30° to 60°. For example, the taper angle β1 may be 30°, 35°, 45°, 50°, 55°, 60°, or the like. A taper angle β2 of the encapsulation unit 91 corresponding to the second light-emitting unit ranges from 30° to 80°. For example, the taper angle β2 may be 30°, 35°, 45°, 55°, 65°, 75°, 80°, or the like. The first light-emitting unit and the second light-emitting unit emit light in different colors.

Through the reasonable setting of the taper angle β1, the encapsulation unit 91 remaining on a side wall of the isolation structure 7 corresponding to the second light-emitting unit can be etched more cleanly, so that the second electrode 5 of the second light-emitting unit can more effectively overlap with the corresponding isolation structure 7.

Through the reasonable setting of the taper angle β2, the encapsulation unit 91 remaining on a side wall of the isolation structure 7 corresponding to a light-emitting unit in the subsequent process (e.g., a third light-emitting unit) can be etched more cleanly, so that the second electrode 5 of the light-emitting unit in the subsequent process can more effectively overlap with the corresponding isolation structure 7.

The structure of the display panel provided in this embodiment is the same as that of the display panel provided in the foregoing embodiments, which is not described in detail herein.

Based on the above, in the present application, the first encapsulation layer 9 remaining on the side wall of the isolation structure 7 corresponding to the second light-emitting unit is side-etched, so that the taper angle β1 of the encapsulation unit 91 corresponding to the first light-emitting unit is not equal to the taper angle β2 of the encapsulation unit 91 corresponding to the second light-emitting unit. Finally, the second electrodes 5 of the first light-emitting unit and the second light-emitting unit can effectively overlap with the corresponding isolation structure 7, thereby improving the display effect of the display panel.

In some possible implementations, referring to FIG. 5, the present application further provides a manufacturing method for a display panel. The method includes the following steps.

In S10, an array substrate 1 is provided.

The array substrate 1 may include a base and a plurality of driving units located on one side of the base. Each driving unit may include one or more semiconductor switching devices. The semiconductor switching device may be formed by a plurality of film layers in the array substrate 1 through cooperation. For example, the semiconductor switching device may be a thin film transistor formed by a plurality of film layers through cooperation.

In S11, an isolation structure 7 is located on one side of the array substrate 1. The isolation structure 7 encloses and forms an isolation opening 6.

Referring to FIG. 6, a first electrode layer is formed on one side of the array substrate 1, and the first electrode layer includes a plurality of first electrodes 2 spaced apart.

Referring to FIG. 7, a pixel defining layer 3 is formed on a side of the first electrode layer away from the array substrate 1, the pixel defining layer 3 includes pixel openings 31 exposing at least part of the first electrode 2, and an orthographic projection of the isolation structure 7 on the array substrate 1 is located between orthographic projections of two adjacent pixel openings 31 on the array substrate 1. The orthographic projection of the pixel opening 31 on the array substrate 1 is located within an orthographic projection of the isolation opening 6 on the array substrate 1.

Referring to FIG. 8, the isolation structure 7 is formed on a side of the pixel defining layer 3 away from the array substrate 1.

In S12, at least part of a light-emitting unit 8 is formed in the isolation opening 6, and a first encapsulation layer 9 is formed on a side of the light-emitting unit 8 away from the array substrate 1. The light-emitting unit 8 includes a first light-emitting unit and a second light-emitting unit. The first encapsulation layer 9 includes a plurality of encapsulation units 91 spaced apart. The encapsulation units 91 extend from a side surface of the isolation structure 7 to a side of the isolation structure 7 away from the array substrate 1. The side surface of the isolation structure 7 is a surface of the isolation structure 7 facing the isolation opening 6. A taper angle is formed between a side of a portion of the encapsulation unit 91 located on the side of the isolation structure 7 away from the array substrate 1 close to the isolation structure 7 and a side of the portion away from the isolation opening 6, and a taper angle of the encapsulation unit 91 corresponding to the first light-emitting unit is not equal to a taper angle of the encapsulation unit 91 corresponding to the second light-emitting unit.

Referring to FIG. 9, a light-emitting functional layer of the first light-emitting unit is formed on the side of the isolation structure 7 away from the array substrate 1.

The light-emitting functional layer may be disconnected at the isolation structure 7, so that at least part of the light-emitting functional layer is located in the isolation opening 6 to form light-emitting portions 4. By controlling an evaporation angle, the light-emitting portions 4 may not be in contact with the isolation structure 7.

Referring to FIG. 10, a second electrode layer is formed on a side of the light-emitting functional layer of the first light-emitting unit away from the array substrate 1.

The second electrode layer may be disconnected at the isolation structure 7, so that at least part of the second electrode layer is located in the isolation opening 6 to form second electrodes 5. By controlling an evaporation angle, the second electrodes 5 may extend from the isolation opening 6 to electrically contact the isolation structure 7 to connect adjacent second electrodes 5 or connect the second electrodes 5 to other circuits. In this way, manufacturing difficulty of the display panel can be reduced.

Referring to FIG. 11, the first encapsulation layer 9 is formed on a side of the second electrode layer away from the array substrate 1.

Referring to FIG. 12, a first etching protection layer 10 is formed in the isolation opening 6 corresponding to the first light-emitting unit.

The first etching protection layer 10 may protect the light-emitting functional layer, the second electrode layer, and the first encapsulation layer 9 that correspond to the first light-emitting unit.

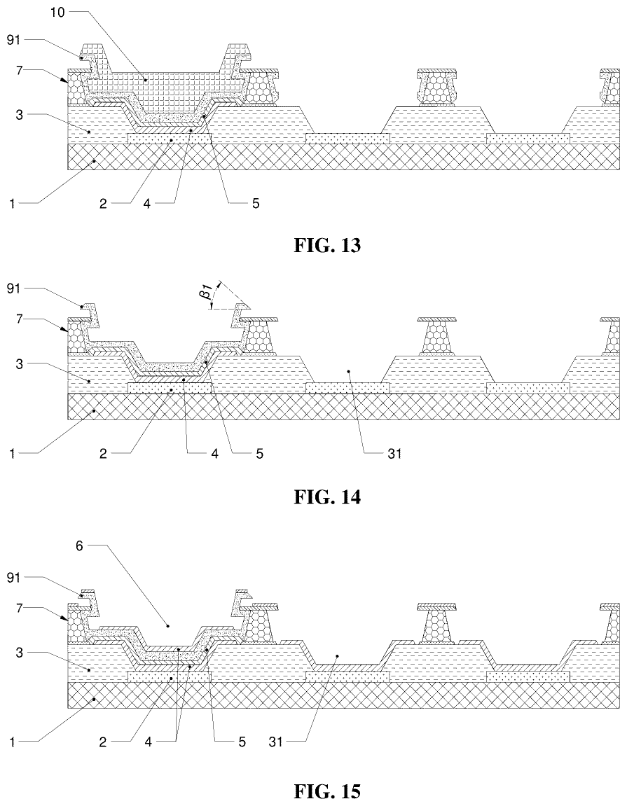

Referring to FIG. 13, along a direction perpendicular to the array substrate 1, the first encapsulation layer 9, the light-emitting functional layer, and the second electrode layer that are not covered by the first etching protection layer 10 are removed.

After the first encapsulation layer 9, the light-emitting functional layer, and the second electrode layer that are not covered by the first etching protection layer 10 are removed along the direction perpendicular to the array substrate 1, part of the first encapsulation layer 9 may remain on side walls of the isolation structure 7 corresponding to the second light-emitting unit and a third light-emitting unit, and the first encapsulation layer 9 remaining on the side walls of the isolation structure 7 corresponding to the second light-emitting unit and the third light-emitting unit may affect an overlapping effect between the second electrodes 5 of the second light-emitting unit and the third light-emitting unit and the corresponding isolation structure 7.

Referring to FIG. 14, the first encapsulation layer 9 located on the side walls of the isolation structure 7 corresponding to the second light-emitting unit and the third light-emitting unit is laterally removed, and the first etching protection layer 10 is removed, to form the light-emitting portion 4, the second electrode 5, and the encapsulation unit 91 in the pixel opening 31 corresponding to the first light-emitting unit. The second electrode 5 extends to be electrically connected to the isolation structure 7 corresponding to the first light-emitting unit. A taper angle β1 formed between a side of a portion of the encapsulation unit 91 corresponding to the first light-emitting unit located on the side of the isolation structure 7 away from the array substrate 1 close to the isolation structure 7 and a side of the portion away from the isolation opening 6 ranges from 30° to 60°.

After the first encapsulation layer 9, the light-emitting functional layer, and the second electrode layer that are not covered by the first etching protection layer 10 are removed, the first electrode 2, the light-emitting portion 4 of the first light-emitting unit, and the second electrode 5 form the first light-emitting unit, and the first light-emitting unit is completely covered by the encapsulation unit 91, thereby reducing risks of contamination of an evaporation device and disconnection of film layers caused by entry of an evaporation material into the device after exposure to the air.

In this way, the light-emitting portion 4, the second electrode 5, and the encapsulation unit 91 can be formed only in the pixel opening 31 corresponding to the first light-emitting unit without a fine metal mask, and the second electrode 5 can be electrically connected to the isolation structure 7, so that the first light-emitting unit can be formed in the pixel opening 31 corresponding to the first light-emitting unit at a lower cost.

The first encapsulation layer 9 located on the side walls of the isolation structure 7 corresponding to the second light-emitting unit and the third light-emitting unit can be removed by side etching, and at the same time the taper angle β1 formed between the side of the portion of the encapsulation unit 91 corresponding to the first light-emitting unit located on the side of the isolation structure 7 away from the array substrate 1 close to the isolation structure 7 and the side of the portion away from the isolation opening 6 may range from 30° to 60°. For example, the taper angle β1 may be 30°, 35°, 45°, 50°, 55°, 60°, or the like.

Referring to FIG. 15, a light-emitting functional layer of the second light-emitting unit is formed on the side of the isolation structure 7 away from the array substrate 1, and the light-emitting functional layer of the second light-emitting unit extends to a side of the encapsulation unit 91 corresponding to the first light-emitting unit away from the array substrate 1.

On the basis of the formation of the first light-emitting unit, the light-emitting functional layer of the second light-emitting unit is continuously formed. The light-emitting functional layer of the second light-emitting unit may cover the encapsulation unit 91 corresponding to the first light-emitting unit. At the same time, the light-emitting portion 4 of the second light-emitting unit may be formed in the pixel opening 31 corresponding to the second light-emitting unit.

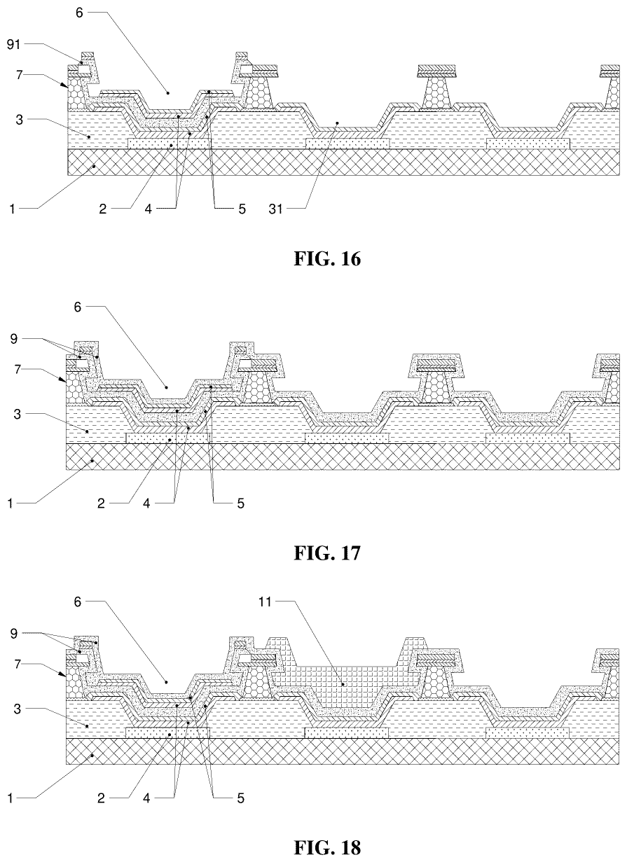

Referring to FIG. 16, a second electrode layer is formed on a side of the light-emitting functional layer of the second light-emitting unit away from the array substrate 1. At the same time, the second electrode 5 of the second light-emitting unit may be formed in the pixel opening 31 corresponding to the second light-emitting unit, and the second electrode 5 of the second light-emitting unit is electrically connected to the corresponding isolation structure 7.

Referring to FIG. 17, the first encapsulation layer 9 is formed on a side of the second electrode layer away from the array substrate 1.

Referring to FIG. 18, a second etching protection layer 11 is formed in the isolation opening 6 corresponding to the second light-emitting unit.

The second etching protection layer 11 may protect the light-emitting functional layer, the second electrode layer, and the first encapsulation layer 9 that correspond to the second light-emitting unit.

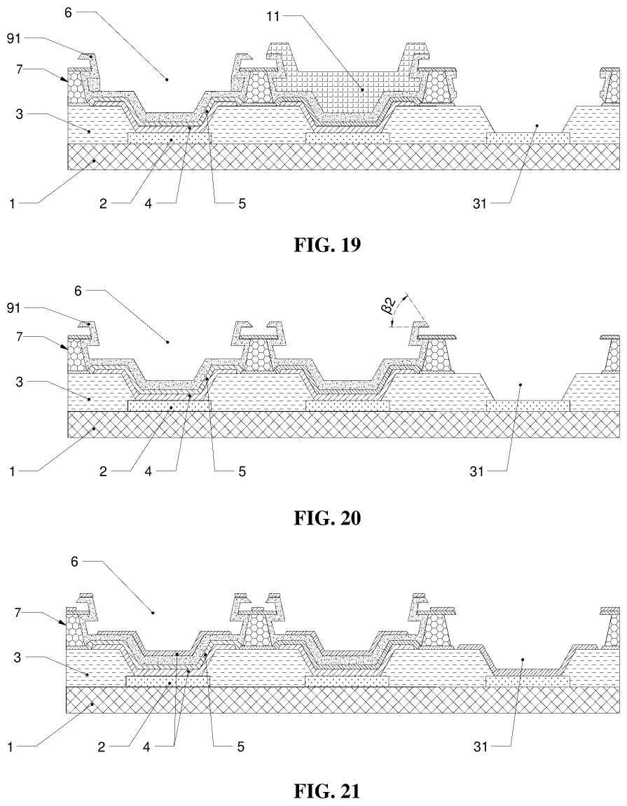

Referring to FIG. 19, along the direction perpendicular to the array substrate 1, the first encapsulation layer 9, the light-emitting functional layer, and the second electrode layer of the second light-emitting unit that are not covered by the second etching protection layer 11 are removed.

After the first encapsulation layer 9, the light-emitting functional layer, and the second electrode layer that are not covered by the second etching protection layer 11 are removed along the direction perpendicular to the array substrate 1, part of the first encapsulation layer 9 may remain on the side wall of the isolation structure 7 corresponding to the third light-emitting unit, and the first encapsulation layer 9 remaining on the side wall of the isolation structure 7 corresponding to the third light-emitting unit may affect an overlapping effect between the second electrode 5 of the third light-emitting unit and the corresponding isolation structure 7.

Referring to FIG. 20, the first encapsulation layer 9 located on the side wall of the isolation structure 7 corresponding to the third light-emitting unit is laterally removed, and the second etching protection layer 11 is removed, to form the light-emitting portion 4, the second electrode 5, and the encapsulation unit 91 in the pixel opening 31 corresponding to the second light-emitting unit. The second electrode 5 extends to be electrically connected to the isolation structure 7 corresponding to the second light-emitting unit. A taper angle β2 formed between a side of a portion of the encapsulation unit 91 corresponding to the second light-emitting unit located on the side of the isolation structure 7 away from the array substrate 1 close to the isolation structure 7 and a side of the portion away from the isolation opening 6 ranges from 30° to 80°.

Since the first encapsulation layer 9 remaining on the side wall of the isolation structure 7 corresponding to the second light-emitting unit is removed before the second light-emitting unit is formed, the second electrode 5 of the second light-emitting unit may extend to be effectively electrically connected to the isolation structure 7 corresponding to the second light-emitting unit.

After the first encapsulation layer 9, the light-emitting functional layer, and the second electrode layer that are not covered by the second etching protection layer 11 are removed, the first electrode 2, the light-emitting portion 4 of the first light-emitting unit, and the second electrode 5 form the second light-emitting unit, and the second light-emitting unit is completely covered by the encapsulation unit 91, thereby reducing risks of contamination of an evaporation device and disconnection of film layers caused by entry of an evaporation material into the device after exposure to the air.

In this way, the light-emitting portion 4, the second electrode 5, and the encapsulation unit 91 can be formed only in the pixel opening 31 corresponding to the second light-emitting unit without a fine metal mask, and the second electrode 5 can be electrically connected to the isolation structure 7, so that the second light-emitting unit can be formed in the pixel opening 31 corresponding to the second light-emitting unit at a lower cost.

The first encapsulation layer 9 located on the side wall of the isolation structure 7 corresponding to the third light-emitting unit can be removed by side etching, and at the same time the taper angle β2 formed between the side of the portion of the encapsulation unit 91 corresponding to the second light-emitting unit located on the side of the isolation structure 7 away from the array substrate 1 close to the isolation structure 7 and the side of the portion away from the isolation opening 6 may range from 30° to 80°. For example, the taper angle β2 may be 30°, 35°, 45°, 55°, 65°, 75°, 80°, or the like.

Referring to FIG. 21, a light-emitting functional layer of the third light-emitting unit is formed on the side of the isolation structure 7 away from the array substrate 1, and the light-emitting functional layer of the third light-emitting unit extends to sides of the encapsulation units 91 corresponding to the first light-emitting unit and the second light-emitting unit away from the array substrate 1.

On the basis of the formation of the first light-emitting unit and the second light-emitting unit, the light-emitting functional layer of the third light-emitting unit is continuously formed. The light-emitting functional layer of the third light-emitting unit may cover the encapsulation units 91 corresponding to the first light-emitting unit and the second light-emitting unit. At the same time, the light-emitting portion 4 of the third light-emitting unit may be formed in the pixel opening 31 corresponding to the third light-emitting unit.

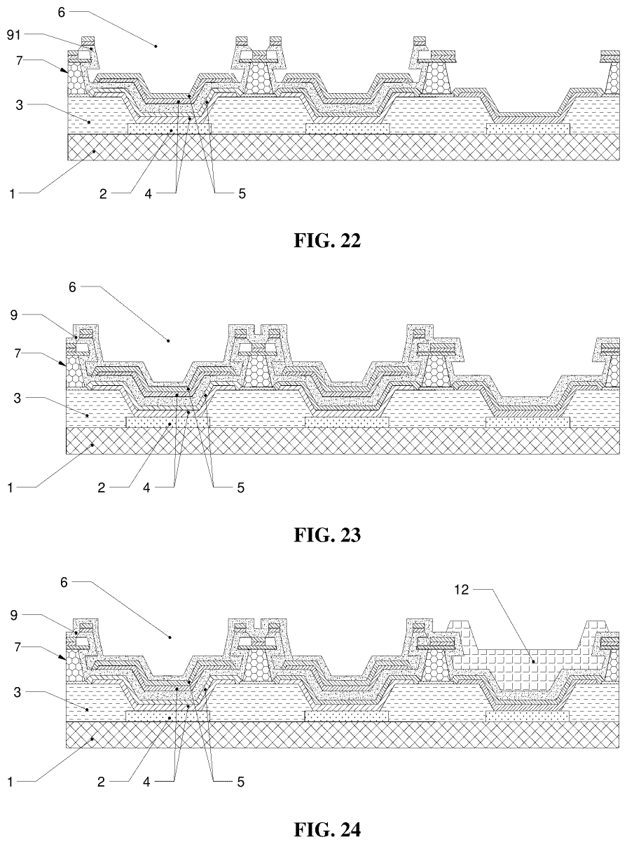

Referring to FIG. 22, the second electrode layer is formed on a side of the light-emitting functional layer of the third light-emitting unit away from the array substrate 1. At the same time, the second electrode 5 of the third light-emitting unit may be formed in the pixel opening 31 corresponding to the third light-emitting unit, and the second electrode 5 of the third light-emitting unit is electrically connected to the isolation structure 7.

Referring to FIG. 23, the first encapsulation layer 9 is formed on a side of the second electrode layer away from the array substrate 1.

Referring to FIG. 24, a third etching protection layer 12 is formed in the isolation opening 6 corresponding to the third light-emitting unit.

The third etching protection layer 12 may protect the light-emitting functional layer, the second electrode layer, and the first encapsulation layer 9 that correspond to the third light-emitting unit.

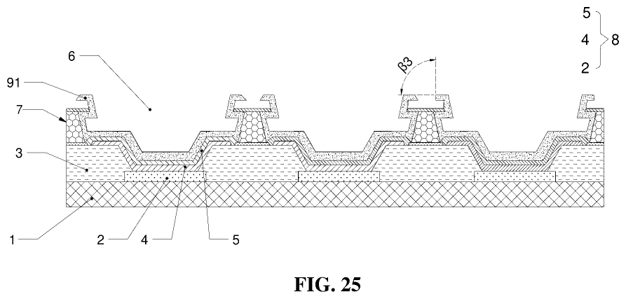

Referring to FIG. 25, the first encapsulation layer 9, the light-emitting functional layer, and the second electrode layer of the third light-emitting unit that are not covered by the third etching protection layer 12 are removed along the direction perpendicular to the array substrate 1, and the third etching protection layer 12 is removed, to form the light-emitting portion 4, the second electrode 5, and the encapsulation unit 91 in the pixel opening 31 corresponding to the third light-emitting unit. The second electrode 5 extends to be electrically connected to the isolation structure 7 corresponding to the third light-emitting unit. A taper angle β3 formed between a side of a portion of the encapsulation unit 91 corresponding to the third light-emitting unit located on the side of the isolation structure 7 away from the array substrate 1 close to the isolation structure 7 and a side of the portion away from the isolation opening 6 ranges from 80° to 90°.

Since the first encapsulation layer 9 remaining on the side wall of the isolation structure 7 corresponding to the third light-emitting unit is removed before the third light-emitting unit is formed, the second electrode 5 of the third light-emitting unit may extend to be effectively electrically connected to the isolation structure 7 corresponding to the second light-emitting unit.

After the first encapsulation layer 9, the light-emitting functional layer, and the second electrode layer that are not covered by the third etching protection layer 12 are removed, the first electrode 2, the light-emitting portion 4 of the first light-emitting unit, and the second electrode 5 form the third light-emitting unit, and the third light-emitting unit is completely covered by the encapsulation unit 91, thereby reducing risks of contamination of an evaporation device and disconnection of film layers caused by entry of an evaporation material into the device after exposure to the air.

In this way, the light-emitting portion 4, the second electrode 5, and the encapsulation unit 91 can be formed only in the pixel opening 31 corresponding to the third light-emitting unit without a fine metal mask, and the second electrode 5 can be electrically connected to the isolation structure 7, so that the third light-emitting unit can be formed in the pixel opening 31 corresponding to the third light-emitting unit at a lower cost.

Since no other light-emitting units 8 may be manufactured after the third light-emitting unit in this embodiment, after the third light-emitting unit is manufactured, there is no need to side-etch a portion of the encapsulation unit 91 corresponding to the third light-emitting unit on the side of the isolation structure 7 away from the array substrate 1. Therefore, the theoretical taper angle β3 of the encapsulation unit 91 corresponding to the third light-emitting unit is 90°. During the manufacturing, there may be a certain error. Therefore, the taper angle β3 of the encapsulation unit 91 corresponding to the third light-emitting unit may range from 80° to 90°. For example, the taper angle β3 may be 80°, 82°, 85°, 88°, 90°, or the like. In this way, the step of side-etching the portion of the encapsulation unit 91 corresponding to the third light-emitting unit on the side of the isolation structure 7 away from the array substrate 1 can be reduced, thereby reducing the manufacturing costs of the display panel.

Based on the above, according to the display panel manufactured with the method in the present application, the second electrode 5 of the light-emitting unit 8 can effectively overlap with the corresponding isolation structure 7, so that the display effect of the display panel can be improved. At the same time, according to a manufacturing sequence of the first light-emitting unit, the second light-emitting unit, and the third light-emitting unit, there is no need to side-etch the portion of the encapsulation unit 91 corresponding to the third light-emitting unit on the side of the isolation structure 7 away from the array substrate 1. Therefore, the manufacturing costs of the display panel can be reduced. The first light-emitting unit, the second light-emitting unit, and the third light-emitting unit emit light in different colors. For example, the first light-emitting unit may be red, the second light-emitting unit may be green, and the third light-emitting unit may be blue.

In some possible implementations, the present application further provides an electronic device. The electronic device includes the display panel in the present application or includes a display panel manufactured with the manufacturing method for a display panel in the present application. The electronic device may include a device with an image processing capability, such as a server, a personal computer, or a notebook computer. Since the electronic device includes the display panel in the present application, the electronic device has a better display effect.

The technical features in the above embodiments may be randomly combined. For concise description, not all possible combinations of the technical features in the above embodiments are described. However, all the combinations of the technical features are to be considered as falling within the scope described in this specification provided that they do not conflict with each other.

The above embodiments only describe several implementations of the present invention, and their description is specific and detailed, but cannot therefore be understood as a limitation on the patent scope of the present invention. It should be noted that those of ordinary skill in the art may further make variations and improvements without departing from the conception of the present invention, and these all fall within the protection scope of the present invention. Therefore, the patent protection scope of the present invention should be subject to the appended claims.

What is claimed is:

1. A display panel, wherein the display panel comprises:
an array substrate;
an isolation structure located on one side of the array substrate, the isolation structure enclosing and forming an isolation opening;
a light-emitting unit at least partially located in the isolation opening, the light-emitting unit comprising a first light-emitting unit and a second light-emitting unit; and
a first encapsulation layer located on a side of the light-emitting unit away from the array substrate, the first encapsulation layer comprising a plurality of encapsulation units spaced apart, the encapsulation units extending from a side surface of the isolation structure to a side of the isolation structure away from the array substrate, the side surface of the isolation structure being a surface of the isolation structure facing the isolation opening; a taper angle being formed between a side of a portion of the encapsulation unit located on the side of the isolation structure away from the array substrate close to the isolation structure and a side of the portion away from the isolation opening, and a taper angle of the encapsulation unit corresponding to the first light-emitting unit being not equal to a taper angle of the encapsulation unit corresponding to the second light-emitting unit.

2. The display panel of claim 1, wherein the taper angle of the encapsulation unit corresponding to the first light-emitting unit ranges from 30° to 60°;
the first light-emitting unit and the second light-emitting unit emit light in different colors.

3. The display panel of claim 1, wherein the taper angle of the encapsulation unit corresponding to the second light-emitting unit ranges from 30° to 80°;
the first light-emitting unit and the second light-emitting unit emit light in different colors.

4. The display panel of claim 1, wherein the display panel further comprises a third light-emitting unit, and a taper angle of the encapsulation unit corresponding to the third light-emitting unit is not equal to the taper angles of the encapsulation units corresponding to the first light-emitting unit and the second light-emitting unit.

5. The display panel of claim 4, wherein the taper angle of the encapsulation unit corresponding to the third light-emitting unit ranges from 80° to 90°;
the first light-emitting unit, the second light-emitting unit, and the third light-emitting unit emit light in different colors.

6. The display panel of claim 1, wherein adjacent encapsulation units are spaced apart on the side of the isolation structure away from the array substrate;
a gap exists between the portion of the encapsulation unit located on the side of the isolation structure away from the array substrate and the side of the isolation structure away from the array substrate; and
a material of the first encapsulation layer comprises an inorganic material.

7. The display panel of claim 1, wherein the light-emitting unit comprises a first electrode layer, a light-emitting functional layer, and a second electrode layer sequentially stacked along a direction away from the array substrate.

8. The display panel of claim 7, wherein the display panel further comprises a pixel defining layer located on a side of the first electrode layer away from the array substrate, and the isolation structure is located on a side of the pixel defining layer away from the array substrate; the pixel defining layer comprises pixel openings exposing at least part of the first electrode, and an orthographic projection of the isolation structure on the array substrate is located between orthographic projections of two adjacent pixel openings on the array substrate.

9. The display panel of claim 8, wherein the orthographic projection of the pixel opening on the array substrate is located within an orthographic projection of the isolation opening on the array substrate.

10. The display panel of claim 1, wherein the isolation structure comprises a first isolation portion and a second isolation portion sequentially stacked along a direction away from the array substrate, and an orthographic projection of the first isolation portion on the array substrate is located within an orthographic projection of the second isolation portion on the array substrate.

11. The display panel of claim 10, wherein a second electrode of the light-emitting unit is electrically connected to the first isolation portion; the isolation structure further comprises a third isolation portion located on a side of the first isolation portion facing the array substrate, the second electrode of the light-emitting unit is electrically connected to the third isolation portion.

12. The display panel of claim 11, wherein a material of the third isolation portion comprises metal; a material of the first isolation portion comprises metal; a material of the second isolation portion comprises metal.

13. The display panel of claim 12, wherein the material of the third isolation portion comprises molybdenum metal; the material of the first isolation portion comprises aluminum metal; the material of the second isolation portion comprises titanium metal.

14. A display panel, wherein the display panel comprises:
an array substrate;
an isolation structure located on one side of the array substrate, the isolation structure enclosing and forming an isolation opening;
a light-emitting unit at least partially located in the isolation opening; and
a first encapsulation layer located on a side of the light-emitting unit away from the array substrate, the first encapsulation layer comprising a plurality of encapsulation units spaced apart, the encapsulation units extending from a side surface of the isolation structure to a side of the isolation structure away from the array substrate, the side surface of the isolation structure being a surface of the isolation structure facing the isolation opening; a taper angle being formed between a side of a portion of the encapsulation unit located on the side of the isolation structure away from the array substrate close to the isolation structure and a side of the portion away from the isolation opening, the taper angle being less than 90°.

15. The display panel of claim 14, wherein the light-emitting unit comprises a first light-emitting unit and a second light-emitting unit, and a taper angle of the encapsulation unit corresponding to the first light-emitting unit ranges from 30° to 60°;
a taper angle of the encapsulation unit corresponding to the second light-emitting unit ranges from 30° to 80°;
the first light-emitting unit and the second light-emitting unit emit light in different colors;
the display panel further comprises a third light-emitting unit, and a taper angle of the encapsulation unit corresponding to the third light-emitting unit is not equal to the taper angles of the encapsulation units corresponding to the first light-emitting unit and the second light-emitting unit;
the taper angle of the encapsulation unit corresponding to the third light-emitting unit ranges from 80° to 90°;
the first light-emitting unit, the second light-emitting unit, and the third light-emitting unit emit light in different colors;
adjacent encapsulation units are spaced apart on the side of the isolation structure away from the array substrate;
a gap exists between the portion of the encapsulation unit located on the side of the isolation structure away from the array substrate and the side of the isolation structure away from the array substrate;
a material of the first encapsulation layer comprises an inorganic material;
the light-emitting unit comprises a first electrode layer, a light-emitting functional layer, and a second electrode layer sequentially stacked along a direction away from the array substrate.
the display panel further comprises a pixel defining layer located on a side of the first electrode layer away from the array substrate, and the isolation structure is located on a side of the pixel defining layer away from the array substrate; the pixel defining layer comprises pixel openings exposing at least part of the first electrode, and an orthographic projection of the isolation structure on the array substrate is located between orthographic projections of two adjacent pixel openings on the array substrate.
the orthographic projection of the pixel opening on the array substrate is located within an orthographic projection of the isolation opening on the array substrate;
the isolation structure comprises a first isolation portion and a second isolation portion sequentially stacked along the direction away from the array substrate, and an orthographic projection of the first isolation portion on the array substrate is located within an orthographic projection of the second isolation portion on the array substrate.
a second electrode of the light-emitting unit is electrically connected to the first isolation portion; the isolation structure further comprises a third isolation portion located on a side of the first isolation portion facing the array substrate, the second electrode of the light-emitting unit is electrically connected to the third isolation portion;
the material of the third isolation portion comprises molybdenum metal; the material of the first isolation portion comprises aluminum metal; the material of the second isolation portion comprises titanium metal; and
the material of the third isolation portion comprises molybdenum metal; the material of the first isolation portion comprises aluminum metal; the material of the second isolation portion comprises titanium metal.

16. A manufacturing method for a display panel, wherein the method comprises:
providing an array substrate;
forming an isolation structure on one side of the array substrate, the isolation structure enclosing and forming an isolation opening; and
forming at least part of a light-emitting unit in the isolation opening, and forming a first encapsulation layer on a side of the light-emitting unit away from the array substrate, the light-emitting unit comprising a first light-emitting unit and a second light-emitting unit, the first encapsulation layer comprising a plurality of encapsulation units spaced apart, the encapsulation units extending from a side surface of the isolation structure to a side of the isolation structure away from the array substrate, the side surface of the isolation structure being a surface of the isolation structure facing the isolation opening; a taper angle being formed between a side of a portion of the encapsulation unit located on the side of the isolation structure away from the array substrate close to the isolation structure and a side of the portion away from the isolation opening, and a taper angle of the encapsulation unit corresponding to the first light-emitting unit being not equal to a taper angle of the encapsulation unit corresponding to the second light-emitting unit.

17. The manufacturing method for the display panel of claim 16, wherein the step of forming an isolation structure on one side of the array substrate comprises:
forming a first electrode layer on one side of the array substrate, the first electrode layer comprising a plurality of first electrodes spaced apart;
forming a pixel defining layer on a side of the first electrode layer away from the array substrate, the pixel defining layer comprising pixel openings exposing at least part of the first electrode, and an orthographic projection of the isolation structure on the array substrate being located between orthographic projections of two adjacent pixel openings on the array substrate; and the orthographic projection of the pixel opening on the array substrate being located within an orthographic projection of the isolation opening on the array substrate; and
forming the isolation structure on a side of the pixel defining layer away from the array substrate.

18. The manufacturing method for the display panel of claim 17, wherein the step of forming at least part of a light-emitting unit in the isolation opening, and forming a first encapsulation layer on a side of the light-emitting unit away from the array substrate comprises:
forming a light-emitting functional layer of the first light-emitting unit on the side of the isolation structure away from the array substrate;
forming a second electrode layer on a side of the light-emitting functional layer of the first light-emitting unit away from the array substrate;
forming the first encapsulation layer on a side of the second electrode layer away from the array substrate;
forming a first etching protection layer in the isolation opening corresponding to the first light-emitting unit;
removing, along a direction perpendicular to the array substrate, the first encapsulation layer, the light-emitting functional layer, and the second electrode layer that are not covered by the first etching protection layer; and
laterally removing the first encapsulation layer located on side walls of the isolation structure corresponding to the second light-emitting unit and a third light-emitting unit, and removing the first etching protection layer, to form a light-emitting portion, a second electrode, and an encapsulation unit in the pixel opening corresponding to the first light-emitting unit, the second electrode extending to be electrically connected to the isolation structure corresponding to the first light-emitting unit; a taper angle formed between a side of a portion of the encapsulation unit corresponding to the first light-emitting unit located on the side of the isolation structure away from the array substrate close to the isolation structure and a side of the portion away from the isolation opening ranging from 30° to 60°.

19. The manufacturing method for the display panel of claim 18, wherein subsequent to the step of laterally removing the first encapsulation layer located on side walls of the isolation structure corresponding to the second light-emitting unit and a third light-emitting unit, and removing the first etching protection layer, the method further comprises:
forming a light-emitting functional layer of the second light-emitting unit on the side of the isolation structure away from the array substrate, the light-emitting functional layer of the second light-emitting unit extending to a side of the encapsulation unit corresponding to the first light-emitting unit away from the array substrate;
forming a second electrode layer on a side of the light-emitting functional layer of the second light-emitting unit away from the array substrate;
forming the first encapsulation layer on the side of the second electrode layer away from the array substrate;
forming a second etching protection layer in the isolation opening corresponding to the second light-emitting unit;
removing, along the direction perpendicular to the array substrate, the first encapsulation layer, the light-emitting functional layer, and the second electrode layer of the second light-emitting unit that are not covered by the second etching protection layer; and
laterally removing the first encapsulation layer located on a side wall of the isolation structure corresponding to the third light-emitting unit, and removing the second etching protection layer, to form a light-emitting portion, a second electrode, and an encapsulation unit in the pixel opening corresponding to the second light-emitting unit, the second electrode extending to be electrically connected to the isolation structure corresponding to the second light-emitting unit; a taper angle formed between a side of a portion of the encapsulation unit corresponding to the second light-emitting unit located on the side of the isolation structure away from the array substrate close to the isolation structure and a side of the portion away from the isolation opening ranging from 30° to 80°.

20. The manufacturing method for the display panel of claim 19, wherein subsequent to the step of laterally removing the first encapsulation layer located on a side wall of the isolation structure corresponding to the third light-emitting unit, and removing the second etching protection layer, the method further comprises:
forming a light-emitting functional layer of the third light-emitting unit on the side of the isolation structure away from the array substrate, the light-emitting functional layer of the third light-emitting unit extending to sides of the encapsulation units corresponding to the first light-emitting unit and the second light-emitting unit away from the array substrate;
forming a second electrode layer on a side of the light-emitting functional layer of the third light-emitting unit away from the array substrate;
forming the first encapsulation layer on the side of the second electrode layer away from the array substrate;
forming a third etching protection layer in the isolation opening corresponding to the third light-emitting unit;
removing, along the direction perpendicular to the array substrate, the first encapsulation layer, the light-emitting functional layer, and the second electrode layer of the third light-emitting unit that are not covered by the third etching protection layer, and removing the third etching protection layer, to form a light-emitting portion, a second electrode, and an encapsulation unit in the pixel opening corresponding to the third light-emitting unit, the second electrode extending to be electrically connected to the isolation structure corresponding to the third light-emitting unit; a taper angle formed between a side of a portion of the encapsulation unit corresponding to the third light-emitting unit located on the side of the isolation structure away from the array substrate close to the isolation structure and a side of the portion away from the isolation opening ranging from 80° to 90°.
